(19) United States
(12) Patent Application Publication
(10) Pub. No.: US 2007/0240759 A1
(43) Pub. Date: Oct. 18, 2007

(54) Stacked thin film photovoltaic module and method for making same using IC processing

(75) Inventor: Peter G. Borden, San Mateo, CA (US)

Correspondence Address: Applied Materials, Inc., P.O. Box 450A, Santa Clara, CA, 95052, US

(73) Assignee: Applied Materials, Inc.

(21) Appl. No.: 11/403,560

(22) Filed: Apr. 13, 2006

(51) Int. Cl. H01L 31/00

(52) U.S. Cl. 136/258

(57) ABSTRACT

In a thin-film photovoltaic (TF PV) module, stacked cells provide efficient conversion of solar energy without being afflicted by conventional problems such as current matching between layers. According to one aspect, the module includes separate terminals for the respective layers in the stack, thus allowing the current in each layer to be different without sacrificing efficiencies gained due to their different bandgaps. According to another aspect of the invention, a processing method according to the invention includes forming interconnects for each layer using etch and deposition processing, including forming separate interconnects for each respective layer, which interconnects can be coupled to respective sets of terminals.

### FIELD OF THE INVENTION

The present invention relates generally to photovoltaic devices, and more particularly to stacked photovoltaic modules and using etch and deposition processing for making the same.

### BACKGROUND OF THE INVENTION

Thin film solar modules offer an attractive way to achieve low manufacturing cost with reasonable efficiency. These modules are made from a variety of materials, including amorphous silicon, amorphous silicon germanium, copper indium gallium selenide (CIGS), and cadmium telluride. A common feature of these solar modules is the deposition on a large area insulator such as a glass sheet.

Another common feature of these modules is the use of scribes and interconnects to divide the large area deposited layer into a number of cells and/or sub-cells. A top view of a typical module divided in this fashion is shown in FIG. 1. As shown in FIG. 1, a module 100 is divided into a plurality of cells 102 (i.e. stripes) that are series connected (e.g. electrically connected together in a horizontal direction between terminals 110 in this drawing) via interconnects 104. The interconnects are typically formed in the module using scribes and conductors. However, it should be noted here that the length L of such modules 100 can be 1 meter or more. Meanwhile, the width of the interconnects (corresponding to the dimension W in FIG. 2), which typically run almost the entire length L of the module, are typically around 700-1000 μm, and the width of the cells (i.e. stripes) are typically about 1 cm. As will be understood by those of skill in the art, FIG. 1 is a simplified, not-to-scale drawing of a typical module, and that the module can further include other passive and active components not shown in FIG. 1 such as electrodes and protect diodes. Moreover, the module will typically also include external contacts and/or be environmentally encapsulated.

As is known, interconnects 104 are made to provide a high voltage, low current output that is less susceptible to series resistance losses. For example, a 1 m² panel at 12% efficiency would provide 120 watts of power. If the cell operating voltage is 0.6 volts, then the current is 200 amps. Since the ohmic loss is I²R (where I is the current and R the resistance), and since the thin conductive films have relatively high resistance, most of the power would be dissipated. However, if the module was divided into 300 stripes, for example, then the voltage across terminals 110 would be 180 volts and the current would be reduced to 0.56 amps. The ohmic losses would likewise be reduced by a factor of 89,000.

One well known method of forming cells for photovoltaic modules includes stacking cells with different bandgaps in order to split the solar spectrum, which method can be used for both crystal and thin-film solar cells. In this method, a high bandgap cell is built above a low bandgap cell. A semiconductor absorbs light with photon energy greater than the bandgap and transmits light with photon energy less than the bandgap. In the stacked configuration, the top cell absorbs the higher energy photons and transmits the lower energy photons to the lower cell. This results in higher efficiency than possible with a single junction cell because each photon can generate one electron-hole pair, and the energy in excess of the bandgap is lost as heat. For example, if a bandgap is 1.1 eV and the photon energy is 2.1 eV, 1.0 eV is lost as heat in the generation of a single electron-hole pair. In the stacked cell, the top cell might have a bandgap of 1.9 eV, so that only 0.2 eV is lost.

If stacked cells are made by growing a series of semiconductor layers to form a set of stacked cells, then the bandgaps must be carefully chosen to match the currents of all cells, as they are connected in series. A current mismatch will force the stack to operate at the current equal to the lowest current cell in the stack, decreasing the overall efficiency. Current matching is at best approximate because it requires control of all parameters in the design of each cell and because the solar spectrum varies with location and time of day.

Therefore, it would desirable to overcome many of the shortcomings of the conventional thin-film photovoltaic devices, including the ability to overcome current mismatch problems with stacked cells. The present invention aims at doing this, among other things.

### SUMMARY OF THE INVENTION

The present invention provides a thin-film photovoltaic (TF PV) module having stacked cells and a process for making such a module that does not require current matching between layers of cells. According to one aspect, the module includes separate terminals for the respective layers in the stack, thus allowing the current in each layer to be different without sacrificing efficiencies gained due to their different bandgaps. According to another aspect of the invention, a processing method according to the invention includes forming interconnects for each layer using etch and deposition processing, including forming separate interconnects for each respective layer, which interconnects can be coupled to respective sets of terminals.

In furtherance of these and other objects, a photovoltaic module according to the invention includes a first layer including thin film photovoltaic material formed on a substrate and patterned into first cells having a first interconnect therebetween, the first interconnect coupled to a first terminal, and a second layer including thin film photovoltaic material formed on top of the first layer, the second layer being patterned into second cells having a second interconnect separate from the first interconnect therebetween, the second interconnect coupled to a second terminal separate from the first terminal.

In additional furtherance of these and other aspects, a method of forming a module according to the invention includes forming a first layer including thin film photovoltaic material on a substrate, processing the first layer using photolithography to form first cells having a first interconnect therebetween, the first interconnect coupled to a first terminal, forming a second layer including thin film photovoltaic material on top of the first layer, and processing the second layer using photolithography to form second cells having a second interconnect separate from the first interconnect therebetween, the second interconnect coupled to a second terminal separate from the first terminal.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a simplified drawing showing a top view of a conventional photovoltaic module;

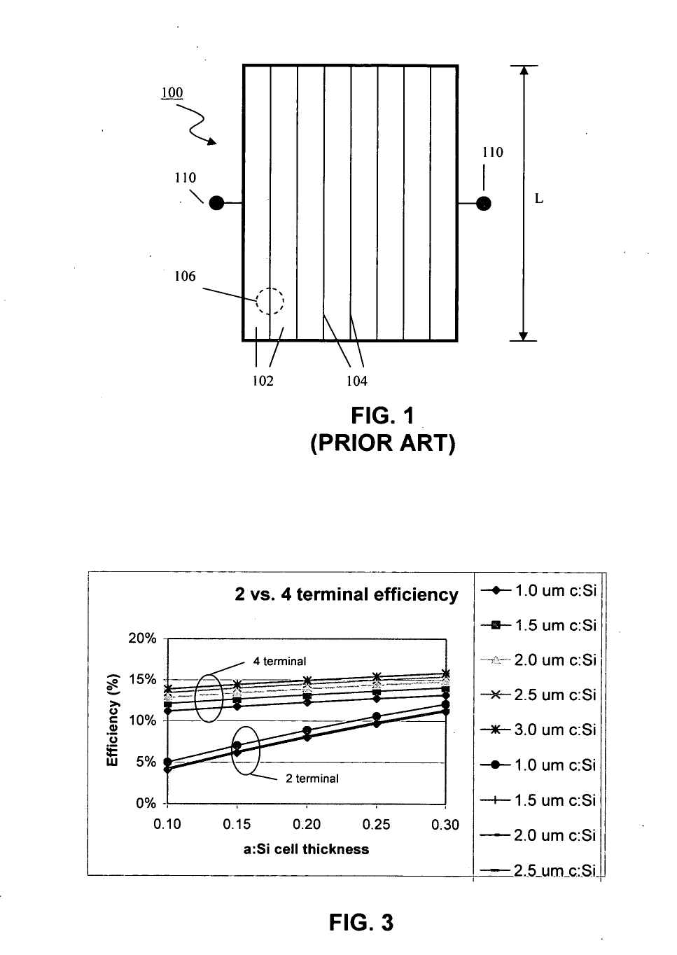

FIGS. 2A-J show successive steps of forming a stacked photovoltaic module in accordance with principles of the invention; and

FIG. 3 is a graph illustrating advantages of a multi-terminal design according to the invention.

### DESCRIPTION OF REFERENCE NUMERALS ON THE DRAWINGS

The following describes the reference numerals used on the drawings. This description is intended to be illustrative rather than limiting and those skilled in the art will appreciate that various substitutions and modifications can be made while remaining within the scope of the invention:
100 module
102 cell
104 interconnect
106 interconnect detail area
110 terminals
200 stack
202 substrate
204 underlying metal
206 semiconducting layer
210 photoresist layer
212 mask
214 aperture
216 conducting step
218 exposed areas
220 insulator
222 transparent conductor
224 metal connector
240 isolation groove
250 metal connector
260 second stack layer

### DETAILED DESCRIPTION OF THE PREFERRED EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

This invention relates to the formation of thin film photovoltaic (TF PV) modules in which cells with different bandgaps are stacked in order to split the solar spectrum. In general, an approach according to the invention is to use multiple terminals that connect the cells of each stack separately. For example, a two-cell stack may have four terminals—two for the top layer of cells and two for the bottom—instead of just two terminals as is typically done. Such a design eliminates the current matching constraint and trades complexity in materials deposition for complexity in processing. Specifically, an aspect of the present invention is to provide an improved process for realizing a stacked TF PV structure with multiple terminals in a manner that is not suggested by the prior art.

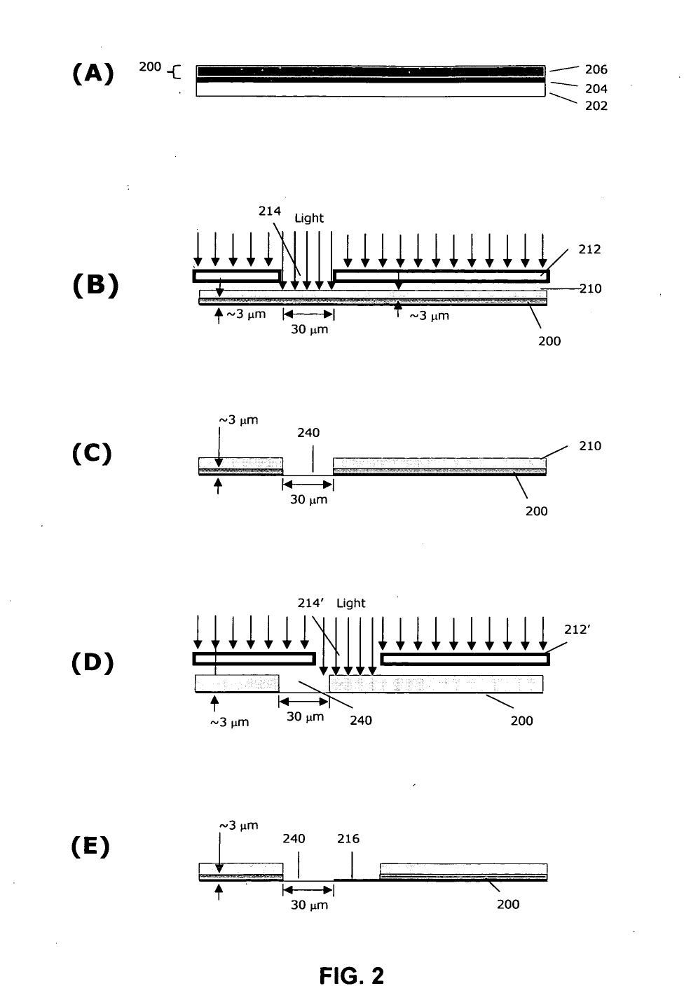

An example process flow for forming stacked photovoltaic cells with multiple terminals according to invention is illustrated in FIGS. 2A-I. The drawings can be considered a greatly enlarged drawing of a portion 106 showing the process with respect to one interconnect of a module such as module 100, taken along a cross-section of the module. It should be noted that the below drawings are not to scale, and relative dimensions of various layers and features, which may appear sized differently in different drawings in order to clarify aspects of the invention, will be specified in the descriptions where examples are appropriate. The drawings are intended for illumination rather than limitation.

In a first step shown in FIG. 2A, the starting material is a photovoltaic stack 200 on a substrate 202 such as a 3 mm thick sheet of glass. In one embodiment, stack 200 includes a 0.1 μm layer 204 corresponding to the opaque metal electrode—typically molybdenum—in contact with the glass substrate 202, and a 2 μm layer 206 of CIGS capped with a 0.07 μm buffer layer of CdS (the CIGS layer or CIGS+CdS layers can be referred to as a semiconducting layer). The initial stack of this embodiment does not include a top transparent conductor; such as ZnO. In alternate embodiments, the ZnO is present; however, because it etches in most acids and bases, its presence will somewhat complicate the process. It should be noted that a top transparent conductor layer can be added later.

In the next step shown in FIG. 2B, stack 200 is coated with a photoresist 210 using, for example a spray, dip or roll-on process. The thickness can be 1-10 μm and the material can be Shipley 3612. As further shown in FIG. 2B, 30 μm wide lines are exposed in the photoresist through an aperture 214 of a mask 212 suspended about 10 μm above or in contact with the stack 200. The exposed resist is developed to complete the pattern.

Next in the step shown in FIG. 2C, a staged etch process is used to isolate adjacent cells. In one possible example described in more detail in co-pending application Ser. No. ______ (AMAT-10936), the contents of which are incorporated herein by reference, an etch mixture, such as a H₂SO₄+H₂O₂ mixture or H₂SO₄+HNO₃ mixture diluted with water, is used to etch the CIGS material 206 through the patterned photoresist down to the underlying metal layer 204. For the underlying Mo layer, an etch such as PAN (phosphoric acid, acetic acid and nitric acid H₃PO₄+CH₃COOH+HNO₃) can be used. These successive etches form a 30 μm wide isolation groove 240 through the stack 200, which can partially or fully run the length of the module (e.g. 1 m). It should be apparent that other lines, substantially parallel to this groove and spaced apart by about 1 cm can also be formed during these steps to define the stripes in the module.

In the next step shown in FIG. 2D, a photoresist layer 210 is re-exposed through aperture 214′ in mask 212′ suspended over the stack 200. In this embodiment, aperture 214′ is aligned to the groove 240 previously formed through the stack 200. Specifically, as shown in this example, aperture 214′ defines a 30 μm opening that is aligned to the right edge (with respect to the orientation of the drawing) of groove 240. The exposed photoresist is developed and the CIGS layer is etched (e.g. using a H₂SO₄+H₂O₂ mixture or H₂SO₄+HNO₃ mixture diluted with water as in the previous step) down to the underlying metal to form a 30 μm conductive step 216 adjacent to groove 240, as shown in FIG. 2E. After this step, the remaining photoresist is removed.

A next step shown in FIG. 2F involves the formation of an insulating region on the exposed sidewalls. This is useful to prevent the cell-to-cell conductor from shorting the left cell. Such an insulator is often not present in thin film photovoltaic modules, but its use improves performance by eliminating the short circuit formed with the conductor. This has the added benefit of enabling use of smaller cells (cell stripes with less width) to increase the voltage of the module and decrease the current. The lower current reduces ohmic losses in the transparent conductors, increasing efficiency. Smaller cells are not used in the prior art for two reasons. First, larger cells suffer less from the edge short. Second, conventional modules are made using laser scribing, a process whose cost and complexity increases with the scribe length. Doubling or tripling the number of stripes doubles or triples the cost of the laser scribing. However, the cost of using a lithographic process according to the invention is independent of the number of scribes, so the use of such processes enables the use of narrower cells.

Accordingly, in the embodiment shown in FIG. 2F, resist 210′ is deposited and then patterned to expose the CIGS edges through openings 218. As should be apparent, an aligned lithographic process such as that described in FIGS. 2B and 2D can be performed. In this example, a lift-off resist such as ProLift 100 from Brewer Science is preferably used, as will become more apparent from below. A thin insulator layer 220 such as SiO₂, SiO₃N₄ or Al₂O₃ is then sputtered to a thickness of 500 Å to 1000 Å.

Removing the photoresist lifts off the insulator deposited thereon, leaving portions of insulator 220 on the opposing walls of the CIGS layer adjacent to the interconnect groove 230 that were exposed through openings 218, as shown in FIG. 2G.

Alternatively, the insulator can also be formed beginning after the step illustrated in FIG. 2C using a low temperature deposition that does not damage the photoresist. When the resist is removed after the step illustrated in FIG. 2E, the insulator is lifted off everywhere except on the exposed sidewall of the left cell.

Another possible implementation of an insulator deposition process, which can be done at low temperatures, is the formation of fluorocarbons using an etcher in deposition mode. Such a technique for the formation of a sidewall insulator is known in CMOS transistor processing and used for the purpose of obtaining anisotropic etching, e.g. deep grooves with approximately vertical sidewalls. Another implementation is the deposition and etchback of a blanket insulator where the insulator is removed from planar regions but remains on sidewalls. This is well known in IC processing where it is called a spacer process, but is unknown in thin film photovoltaic processing, and is therefore novel in this context. Another possible example process is a room temperature sputter deposition of an insulator such as silicon dioxide or silicon monoxide

Next, as shown in FIG. 2G, a layer 222 of a transparent conductor such as 0.7 μm of ZnO, aluminum doped zinc oxide (AZO) or ITO is deposited over the surface of the stack 200. In a preferred embodiment a thin dielectric film is also deposited over the TCO to provide protection for subsequent processing. This may be SiO₂ or Si₃N₄ on the order of 500 to 1000 Å thick, although other thickness may be used. An important consideration of the thickness is to form an anti-reflection coating that maximizes light transmission into the cell.

Then, in a next step shown in FIG. 2I, the layer 222 is patterned (e.g. using lithographic techniques as described in FIGS. 2B and 2D, for example, including etching with a HCl or CH₃COOH solution), to form a series connection 224 between adjacent cells. As shown in FIG. 2I, the insulator material 220 on the sidewall of the left cell underlies the connection 224, thus eliminating the current shunt path formed when the conductor covers the edge of the cell.

As should be apparent, the connection 224 can be formed between each stripe in the module, and thus provides a continuous series connection between cells that can be further connected to terminals at the edges of the module.

It is now possible to use a similar processes to form additional cells stacked on the structure shown in FIG. 2I. First, however, an insulator such as SiO₂ or Si₃N₄ is preferably deposited, again with consideration of the thickness to form an anti-reflection coating that maximizes light transmission into the cell.

A new stack of layers such as those in stack 200 shown in FIG. 2A are then deposited to form a photovoltaic cell structure. Those skilled in the art of stacked cells will understand how to design layers with different bandgaps according to desired performance or applications, and so details thereof will be omitted here. However, one preferred constraint is that the deposition be performed in a manner and/or temperature that does not adversely affect the bottom cell. For example, an amorphous silicon cell structure, with a bandgap of 1.75 eV could be deposited over a CIGS cell structure on the order of 200 degrees C. without adversely affecting the underlying cell.

Depending on the materials used, this new stack can then be patterned using the etch processing shown in FIGS. 2B to 2E, and then interconnected with the same processing shown in FIGS. 2F to 2I to form a new layer 260 of interconnected cells tacked on top of the previous layer 200, as shown in the simplified drawing of FIG. 2J. According to an aspect of the invention, as further shown in FIG. 2J, this processing forms a separate connection 250 that can be terminated at separate terminals from those connected to connection 224.

It should be noted that a self-aligned etch and deposition process such as that described in co-pending application Ser. No. ______ (AMAT-10668), the contents of which are incorporated herein by reference, could be used to form the first conductive step 216. The co-pending application suggested using a self-aligned process because the cost of photolithographic steppers is prohibitive. However, if one is satisfied with lower resolution, it is possible to use photolithography with relatively low cost. For example, proximity steppers used for color filter exposures on flat panel displays offer 7 μm resolution and 1 μm overlay accuracy. These are well within the requirements for photovoltaic interconnects, which are typically>20 μm wide. Such steppers have throughputs>46 substrates per hour for Gen 8 (2.2×2.4 meters). As a rough estimate, assuming a panel efficiency of 10%, three exposures per panel, a stepper cost of $6.4 million amortized over five years, 95% yield and 80% up-time, each stepper can process 50 megawatts of panels per year at a lithography cost of only 2.5¢/watt, small compared to a target cost of $1.00/watt.

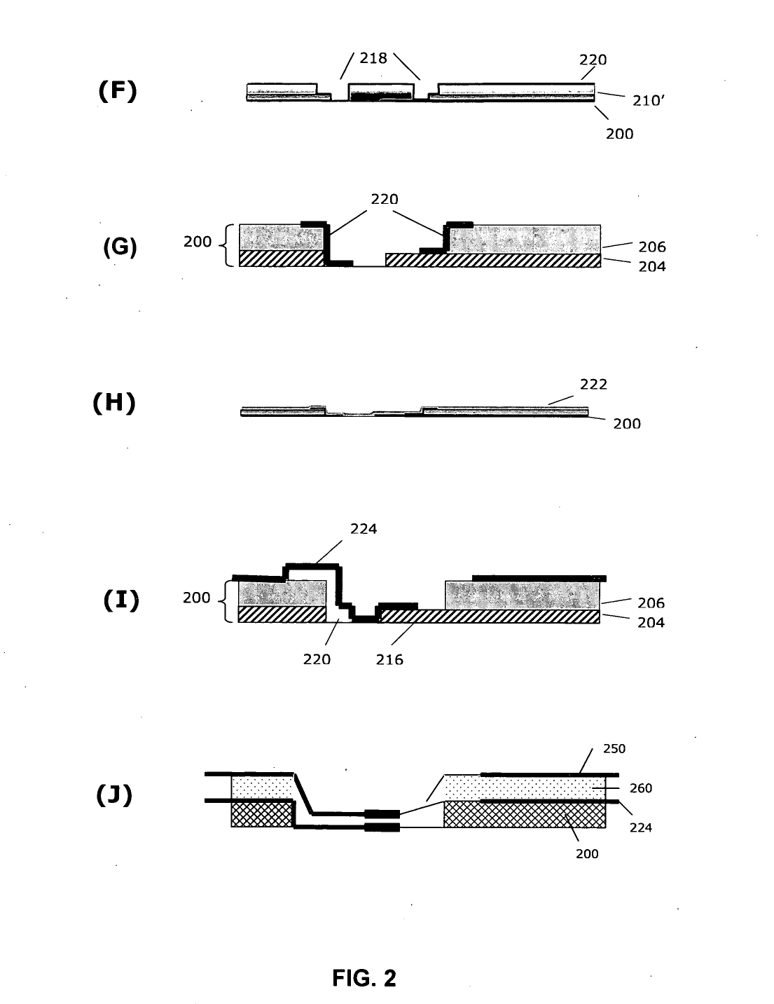

It should be further noted that it is possible to estimate the performance gain resulting from the use of multiple terminals according to the invention. For example, certain benefits of the approach of the invention can be verified by calculations for the current in a top cell of amorphous silicon and a bottom cell of micro-crystal silicon as a function of the thickness of the top and bottom cell. According to these calculations, as illustrated by the graph in FIG. 3, the present inventors have discovered that, with a two-terminal device, the top cell limits the current, which is substantially independent of the thickness of the bottom cell. With a four-terminal device, however, the full efficiency of the bottom cell is realized, resulting in a significant efficiency gain. Therefore, the present invention recognizes that is attractive to make a four-terminal cell, even if the additional processing adds manufacturing cost. Note that a three-terminal cell is a version of a four-terminal cell if one of the terminals is common.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A method comprising:
forming a first layer including thin film photovoltaic material on a substrate;
processing the first layer using photolithography to form first cells having a first interconnect therebetween, the first interconnect coupled to a first terminal;
forming a second layer including thin film photovoltaic material on top of the first layer; and
processing the second layer using photolithography to form second cells having a second interconnect separate from the first interconnect therebetween, the second interconnect coupled to a second terminal separate from the first terminal

2. A method according to claim 1, wherein the step of processing the first layer includes etching the first layer to form an isolation groove between two of the first cells.

3. A method according to claim 2, wherein the first layer includes a metal layer underlying a semiconducting layer, and wherein the step of processing the first layer further includes etching the first layer to expose a portion of the underlying metal layer adjacent the isolation groove, the exposed portion being coupled to a first one of the two first cells, but electrically isolated from a second one of the two first cells by the isolation groove.

4. A method according to claim 3, wherein the step of processing the first layer further includes:
depositing a top conducting layer; and
patterning the top conducting layer to couple the semiconducting layer of the second first cell to the exposed portion across the isolation groove.

5. A method according to claim 4, further comprising depositing insulator material on a sidewall of the semiconducting layer of the second first cell before depositing the top conducting layer.

6. A method according to claim 1, further comprising depositing an insulating layer between the steps of forming the first and second layers and for the purpose of insulating the photovoltaic materials of the first and second layers.

7. A method according to claim 1, wherein the step of processing the second layer includes etching the second layer to form an isolation groove between two of the second cells.

8. A method according to claim 7, wherein the second layer includes a metal layer underlying a semiconducting layer, and wherein the step of processing the second layer further includes etching the second layer to expose a portion of the underlying metal layer adjacent the isolation groove, the exposed portion being coupled to a first one of the two second cells, but electrically isolated from a second one of the two second cells by the isolation groove.

9. A photovoltaic module comprising:
a first layer including thin film photovoltaic material formed on a substrate and patterned into first cells having a first interconnect therebetween, the first interconnect coupled to a first terminal; and
a second layer including thin film photovoltaic material formed on top of the first layer, the second layer being patterned into second cells having a second interconnect separate from the first interconnect therebetween, the second interconnect coupled to a second terminal separate from the first terminal.

10. A module according to claim 9, wherein the first layer includes an isolation groove between two of the first cells.

11. A module according to claim 10, wherein the first layer includes a metal layer underlying a semiconducting layer, and wherein the first layer further includes an exposed portion of the underlying metal layer adjacent the isolation groove, the exposed portion being coupled to a first one of the two first cells, but electrically isolated from a second one of the two first cells by the isolation groove.

12. A module according to claim 11, wherein the first layer further includes a top conducting layer above the semiconductor layer, the top conducting layer being patterned to couple the semiconducting layer of the second first cell to the exposed portion across the isolation groove.

13. A module according to claim 4, further comprising insulator material on a sidewall of the semiconducting layer of the second first cell that insulates the semiconductor layer from the top conducting layer.

14. A module according to claim 9, further comprising an insulating layer between the first and second layers which insulates the photovoltaic materials of the first and second layers.
